(19) United States
(12) Patent Application Publication
(10) Pub. No.: US 2026/0142441 A1
(43) Pub. Date: May 21, 2026

(54) Vertical-Cavity Surface-Emitting Laser with Reduced Bondpad Parasitic Capacitances

(71) Applicant: PicoJool, Inc., Palo Alto, CA (US)

(72) Inventor: Albert T Yuen, Palo Alto, CA (US)

(73) Assignee: PicoJool, Inc., Palo Alto, CA (US)

(21) Appl. No.: 19/392,172

(22) Filed: Nov. 18, 2025

Related U.S. Application Data
(60) Provisional application No. 63/723,305, filed on Nov. 21, 2024.

(51) Int. Cl. H01S 5/183; H01S 5/0234

(52) U.S. Cl. CPC H01S 5/18322; H01S 5/0234; H01S 5/18394

(57) ABSTRACT

A vertical-cavity surface-emitting laser (VCSEL) includes a top surface with a patterned metal area that has an active bondpad and a distinct probe pad, both coupled to the VCSEL top contact. The patterned metal area is optimized to exhibit parasitic capacitance lower than 30% above a minimum achievable capacitance. The probe pad is configured for wafer-level testing, while the active bondpad is configured for subsequent bonding according to a chosen bond technology such as flip-chip bonding or hybrid bonding.

### REFERENCES

This application claims priority from U.S. provisional patent application Ser. No. 63/723,305, entitled “Bottom-Emitting VCSEL with Tiny Probe Pad and Tiny Flip Chip Bump,” filed on Nov. 21, 2024. The priority application is hereby incorporated by reference, as if it is set forth in full in this specification.

### BACKGROUND

### Technical Field

The disclosed implementations relate generally to systems and methods used in photonics, optical communication and LiDAR, and in particular to those for the design and production of vertical-cavity surface-emitting lasers (VCSELs).

### Context

VCSELs are a category of semiconductor laser devices in which laser emission occurs in a direction perpendicular to the planar top surface of the wafers on which the semiconductor chips are fabricated.

### BRIEF DESCRIPTION OF THE DRAWINGS

The technology will be described with reference to the drawings, in which:

FIG. 1 illustrates part of a semiconductor wafer 100 with a conventional vertical-cavity surface-emitting laser (VCSEL 110).

FIG. 2 illustrates a top view of the example conventional semiconductor wafer 100.

FIG. 3 illustrates an example implementation 300 that uses much smaller bondpads, allowing higher speed electric signals to reach VCSEL 310.

FIG. 4 illustrates a view of the top surface of this implementation 300.

In the figures, like reference numbers may indicate functionally similar elements. The systems and methods illustrated in the figures—and described in the Detailed Description below—may be arranged and designed in a wide variety of different implementations. Neither the figures nor the Detailed Description are intended to limit the scope as claimed. Instead, they merely represent examples of different implementations.

### DETAILED DESCRIPTION

Vertical-cavity surface-emitting lasers (VCSELs) are a category of semiconductor laser devices in which laser emission occurs in a direction perpendicular to the planar top surface of the wafers on which the semiconductor chips are fabricated. This geometry allows for more convenient testing (relative to what is possible with edge-emitting lasers) during device fabrication, since VCSEL chips can be tested while they're still part of the wafer, allowing problems to be identified at an early stage when it may still be possible to resolve them, whereas edge-emitting laser chips need to be cut from the wafer before they can be tested. Additionally, VCSELs can be produced in 2-D arrays, which allows for many applications not achievable with edge-emitting lasers.

VCSELs are usually made in a gallium arsenide (GaAs) semiconductor process. They include an active region of a few microns thick, sandwiched between two semiconductor Bragg mirrors, made of layers of epitaxial aluminum gallium arsenide (AlGaAs). The structure sits on a semiconductor substrate (the GaAs wafer). The upper and lower mirrors include doped P-type and N-type materials and form a diode junction at the active region. When the diode carries a current, the active region emits photons. Photons of the laser's wavelength are reflected and amplified by the two mirrors. The mirrors have high, but unequal reflectivity, and eventually the amplified photons leave through the mirror with the lower reflectivity.

To enable communication, light may be modulated at the source (in this case the VCSEL) or later. In that case, the source may generate a steady stream of light, and some external modulator varies the amplitude of the light at a later stage. For various reasons it is attractive to modulate at the source, so the speed of VCSELs has been a longtime subject of research. Electrical, thermal, and optical issues have been found to limit the bandwidth. Over the years, many ways have been published to increase the bandwidth, usually focusing on physical effects inside the VCSEL. However, we feel that the impact of packaging related issues has been mostly overlooked.

An important sub-category is bottom-emitting VCSELs, which are designed such that the generated optical signals are directed to pass through the chip's body before emerging from the device. The top surface of such chips may include metallic bonding pads and optionally “bumps”, allowing the chip to be mounted upside down in a “flip-chip” process. Flip-chip mounting has the advantage that shorter electrical traces can be used with less inductance, resulting in higher signal speeds than can be obtained with traditional bond wire connections. A flip-chip can be mounted directly onto another chip that includes the electronics that steers the VCSEL. In some cases, the flip-chip can be “thinned” after mounting. Thinning is the process of removing part of the semiconductor substrate to reduce optical losses for the optical signal while it travels from the top of the chip where it is generated to the bottom of the chip where it is emitted. Some flip-chip bumps serve as electrical contacts for the signal steering the laser. Other bumps may serve to mechanically stabilize the VCSEL chip and have no electrical function.

In currently available devices, the bumps that are used for flip-chip bonding are also used to enable testing of the chip during the earlier wafer probe stage. If the devices are intended for eventual high-speed operation, there are two competing requirements for the bumps. One is to keep their dimensions small enough to minimize parasitic capacitance which can otherwise significantly limit the devices'frequency response. The other is to make the bumps sturdy enough, which in practice means large enough, to withstand the wear and tear caused by making and breaking contact with the test probes used in wafer-scale test processes. This results in compromised products, where device performance (speed) is sacrificed for reliability.

The technology disclosed herein solves this problem by creating separate contacts for probing and for use in final production and using smaller bumps and bondpads to minimize parasitic capacitances so that significantly higher speeds can be obtained without loss of reliability.

### Terminology

As used herein, the phrase “one of” should be interpreted to mean exactly one of the listed items. For example, the phrase “one of A, B, and C” should be interpreted to mean any of: only A, only B, or only C. The phrase “A or B”, when used in a claim should be interpreted as either A or B. However, when used elsewhere in the document, it may mean either A or B, or both A and B.

As used herein, the phrases “at least one of” and “one or more of” should be interpreted to mean one or more items. For example, the phrase “at least one of A, B, or C”, the phrase “one or more of A, B, or C”, and also the phrase “A, B, and/or C” should be interpreted to mean any combination of A, B, and/or C. The phrase “at least one of A, B, and C” means at least one of A and at least one of B and at least one of C.

Unless otherwise specified, the use of ordinal adjectives first, second, third, etc., to describe an object, merely refers to different instances or classes of the object and does not imply any ranking or sequence.

The terms “comprising” and “consisting” have different meanings in this patent document. An apparatus, method, or product “comprising” (or “including”) certain features means that it includes those features but does not exclude the presence of other features. On the other hand, if the apparatus, method, or product “consists of” (or “contains”) certain features, the presence of any additional features is excluded.

The term “coupled” is used in an operational sense and is not limited to a direct or an indirect coupling. “Coupled to” is generally used in the sense of directly coupled, whereas “coupled with” is generally used in the sense of directly or indirectly coupled. Coupled in an electronic system may refer to a configuration that allows a flow of information, signals, data, or physical quantities such as electrons between two elements coupled to or coupled with each other. In some cases, the flow may be unidirectional, in other cases the flow may be bidirectional or multidirectional. Coupling may be galvanic (in this context meaning that a direct electrical connection exists), capacitive, inductive, electromagnetic, optical, or through any other process allowed by physics.

The term “connected” is used to indicate a direct connection, such as electrical, optical, electromagnetic, or mechanical, between the things that are connected, without any intervening things or devices.

The terms “interconnect” and “interconnection” are used to indicate (an) electrical coupling or (a) photonic coupling, which may be direct or indirect.

The term “configured” to perform a task or tasks is a broad recitation of structure generally meaning having circuitry that performs the task or tasks during operation. As such, the described item can be configured to perform the task even when the unit/circuit/component is not currently on or active. Similarly, various items may be described as performing a task or tasks, for convenience in the description. Such descriptions should be interpreted as including the phrase configured to.

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B”. This phrase specifies that B is a factor that is used to determine A or that affects the determination of A. This phrase does not foreclose that the determination of A may also be based on some other factor, such as C. This phrase is also intended to cover an implementation in which A is determined based solely on B. The phrase based on is thus synonymous with the phrase based at least in part on.

The terms “substantially”, “close”, “approximately”, “near”, and “about” refer to being within minus or plus 20% of an indicated value, unless explicitly specified otherwise.

The following terms or acronyms used herein are defined at least in part as follows:
“Current aperture”—a region that confines the electrical current to a specific area, preventing it from spreading laterally through the active layer. The current aperture may be fabricated by creating undercuts in the active layer, and filling the undercuts from the side with a non-conductive material, such as an oxide or other material from a passivation layer.
“DBR”—distributed Bragg grating—a partially or highly reflective area comprising multiple layers with alternating optical properties and/or thickness.
“Flip-chip bonding”—a method for mechanically and electrically coupling an IC or chip to another IC or chip, to a substrate, or to a package, where the die is inverted (“flipped”) and attached to the other IC or chip, the substrate, or the package, via bumps, typically solder bumps, Cu-pillar bumps, or gold bumps.
“Hybrid bonding”—a method for mechanically and electrically coupling an IC or chip to another IC or chip, to a substrate, or to a package, where the die is flipped and directly attached to the other IC or chip, the substrate, or the package, without intervening bumps.
“IC” or “chip”—integrated circuit—a monolithically integrated circuit, i.e., a single semiconductor die which may be delivered as a bare die or as a packaged circuit.
“MOCVD”—metal-organic chemical vapor deposition
“Quantum well”—a nanometer-thin layer of material that confines electrons in one dimension, making their motion free in only two directions.
“VCSEL”—a vertical-cavity surface-emitting laser.

### Implementations

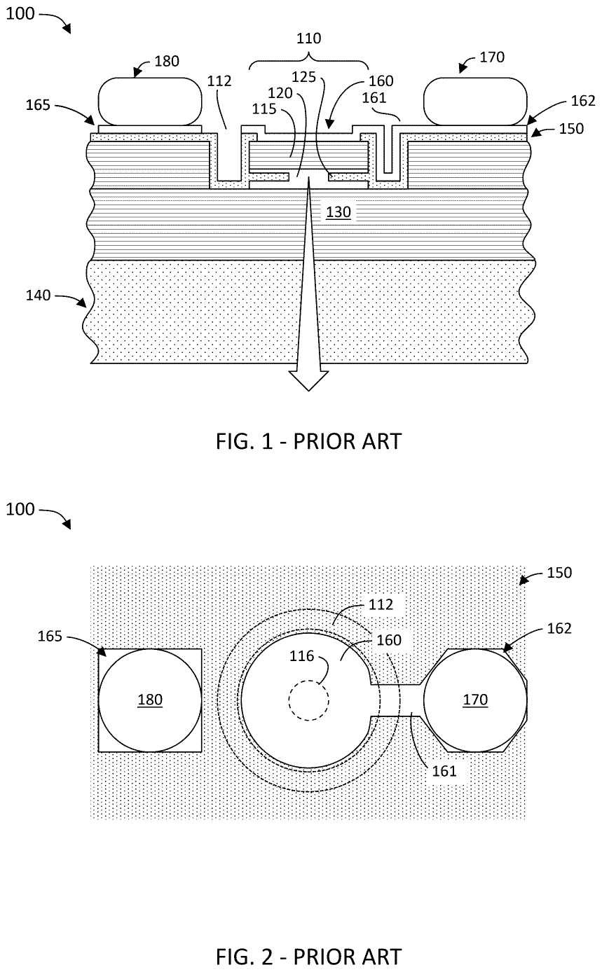

FIG. 1 illustrates part of a semiconductor wafer 100 with a conventional vertical-cavity surface-emitting laser (VCSEL 110). The drawing is not accurate to scale. VCSEL 110 may have been made with standard epitaxial layer depositing techniques (such as metal-organic chemical vapor deposition (MOCVD)), beginning with a substrate 140. VCSEL 110 includes a top reflector 115, an active region 120, and a bottom reflector 130. In this case, top reflector 115 is highly reflective, and bottom reflector 130 is partially reflective, so that the laser beam is emitted from the bottom, i.e., through bottom reflector 130 and substrate 140. VCSEL 110 may be fully or partially surrounded by an etched trench 112. An advantage of a bottom-emitting VCSEL is that it can be mounted upside-down (flipped) onto another IC or chip, to a substrate, or to a package in a flip-chip bonding or hybrid bonding technology, rather than a wire-bond technology, where long bond wires introduce parasitic inductance slowing down electrical signals to the VCSEL. Flip-chip and hybrid bonding don't have this problem, although they still have to cope with parasitic capacitances that slow down the signals. Nevertheless, even VCSEL chips that are not flipped may not always use wire bonds, and the technology presented herein is equally valid for top-emitting and bottom-emitting VCSELs.

The active region 120 includes one or more quantum wells that generate photons when an electric current passes through them. A quantum well is a very thin (in the order of a nanometer) layer of material that confines electrons in one dimension, making their motion free in only two directions. This confinement, a result of a heterostructure with a semiconductor layer sandwiched between two others with different band gaps, leads to discrete energy levels and modifies the electronic and optical properties of the material. In some cases, active region 120 includes one or more tunnel diodes that separate stacked quantum wells. Active region 120 also usually includes one or more current apertures in between electrically insulating undercuts 125 that confine the activation current to the center of the VCSEL. The activation current enters VCSEL 110 from (optional) active bump 170 via active bondpad 162, connection trace 161, and top contact 160, and exits VCSEL 110 either through substrate 140 or through a contact to the bottom reflector 130. For example, etched trench 112 may be deep enough to provide the return current contact to bottom reflector 130 or even to substrate 140. In some cases, a return current contact is at the bottom of substrate 140. The return current contact has not been drawn. In some cases, active bump 170, active bondpad 162, connection trace 161, and top contact 160 are gold plated to help support higher speed signals.

The top reflector 115 and the bottom reflector 130 may be made as distributed Bragg grating reflectors (DBRs), i.e., stacks of alternating epitaxial layers of materials with a different refractive index, or by periodic variation of the height or of another characteristic. The choice of materials, the individual layers'height, and the number of layers determines the total amount of reflectivity for a particular wavelength of light.

Apart from an active bump 170, a VCSEL chip may also include one or more inactive bumps 180 that provide mechanical stability. For example, a bottom-emitting VCSEL chip with fewer than three bumps at its inverted top surface would not rest unbalanced on top of another chip. The inactive bumps 180 have no electrical function. They may sit on a dummy contact plate 165 so that the inactive bumps 180 reach the same height as the active bump 170. Both the active bump 170 and inactive bumps 180 are separated from the epitaxial layers of the top reflector 115 by, for example, a passivation layer 150 that provides electrical insulation.

When active bondpad 162 or active bump 170 is used during wafer probing, it may get malformed or damaged, especially if its size is small. Therefore, on a conventional VCSEL active bump 170 and inactive bumps 180 may have a diameter of 50 microns or more. This allows some damage from wafer probing, without affecting the reliability of the bond between the bump and the bondpad. However, contemporary manufacturing techniques allow bondpads and bumps as small as 20 or even 10 microns, which introduce much lower parasitic capacitance, but the use of those in a conventional VCSEL 110 would create reliability issues due to the damage or deformation sustained during wafer probing.

FIG. 2 illustrates a top view of the example conventional semiconductor wafer 100. This top view shows laser aperture 116 through which the laser emission will occur, perpendicular to the plane of the drawing, and directed downwards away from the viewer. Also drawn are etched trench 112 and a patterned metal layer which includes active bondpad 162, connection trace 161, and top contact 160. The patterned metal layer may be plated with gold (Au) or another highly conductive material. FIG. 2 further shows the location of dummy contact plate 165 and inactive bumps 180. Although shown close to VCSEL 110 in the drawing, inactive bumps 180 don't need to be close by the VCSEL, and they don't significantly contribute to performance degradation.

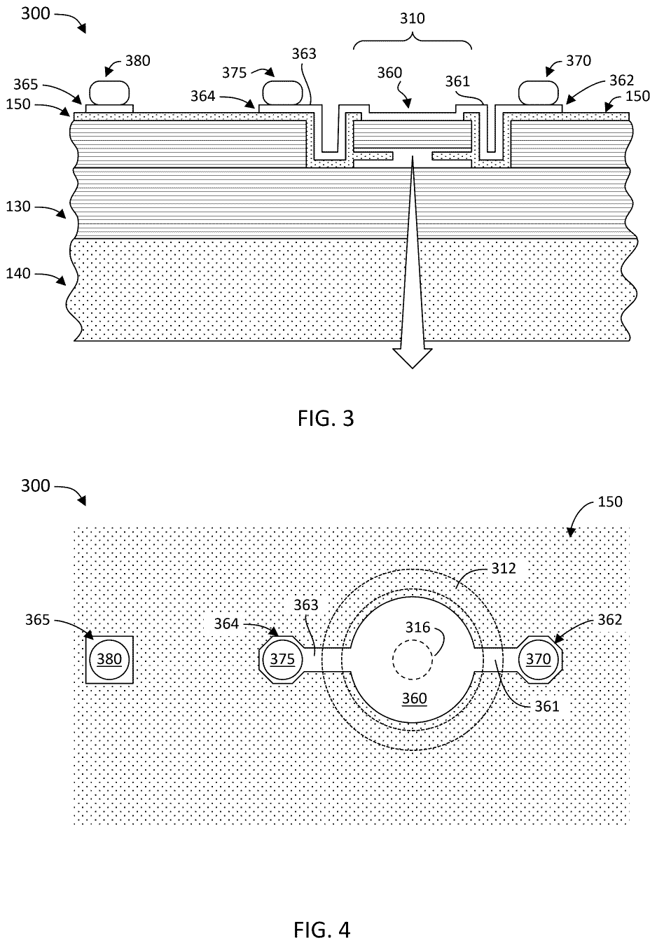

FIG. 3 illustrates an example implementation 300 that uses much smaller bondpads, allowing higher speed electric signals to reach VCSEL 310. Again, the drawing is not accurately to scale. Implementation 300 introduces a separate probe pad 364 and optionally probe bump 375 that are used only during wafer probing, but not in end products. Probe pad 364 is distinct from active bondpad 362 and prepared for wafer-level testing, so should it be deformed or otherwise damaged during wafer probing, then this will not change reliability of signals through (optional) active bump 370, active bondpad 362, or trace 361. As a result, all pads and bumps, including inactive bumps 380, can be smaller, and a lower total parasitic capacity allows a higher VCSEL performance. The layout of the top surface including top contact 360 and associated traces and pads is different than in FIG. 1, where the VCSEL interconnects with only one bondpad. As in conventional VCSELs, all bumps are optional, and none are needed in a hybrid bonding technology.

In some implementations, probe bump 375 is omitted altogether, and only probe pad 364 is supplied. While top contact 160 may be plated with gold, copper, or another material between VCSEL 310 and active bump 370, the metal pattern may be unplated at the location of trace 363 and probe pad 364.

To enable the high performance of VCSEL 310, the patterned metal surface area including the probe pad (364) and the active bondpad (362) is optimized for low parasitic capacitance. The low parasitic capacitance may have any value below 30% above the minimum parasitic capacitance, which may be the parasitic capacitance of the VCSEL top contact plus the parasitic capacitance of a metal surface area of one thousand (1,000) square microns. The 1,000 square microns represents an estimate of the area of two 20×20 micron bondpads and their traces to top contact 360.

FIG. 4 illustrates a view of the top surface of this implementation 300. The top surface includes the patterned metal that includes active bondpad 362, trace 361, top contact 360, trace 363 and probe pad 364. The probe pad 364 is distinct from active bondpad 362. The probe pad 364 is prepared (configured) for wafer-level testing, and active bondpad 362 is prepared for bonding, for example using flip-chip bonding or hybrid bonding. The probe pad 364 and the active bondpad 362 may be square, rectangular, or substantially circular in shape (viewed from above), which includes hexagonal, octagonal, and other polygonal shapes. The surface area of the patterned metal is optimized for low parasitic capacitance, wherein the low parasitic capacitance is below 30% above the minimum parasitic capacitance. The minimum parasitic capacitance is the capacitance of the metal surface area of top contact 360 plus the capacitance of active bondpad 362 plus the capacitance of probe pad 364, plus the capacitance of the interconnecting traces (361 and 363), which may be estimated at 30% of the capacitance of active bondpad 362 and probe pad 364). In numbers, with a minimum bondpad/probe pad size of 20 microns across, this may come to the capacitance of top contact 360 plus 1,000 square microns. FIG. 4 shows etched trench 312 which in this example is all around VCSEL 310, but in other implementations it may be partially around VCSEL 310, and it may be partitioned into multiple smaller trenches. Again, this top view shows laser aperture 316 through which the laser emission will occur, perpendicular to the plane of the drawing, and directed downwards away from the viewer.

FIGS. 3-4 show probe pad 364/active bump 370 and probe bump 375 on opposite sides of VCSEL 310. In other implementations, they may have any other orientation versus each other, including that they may be on the same side of VCSEL 310 and share a single (but extended) trace 361 that crosses etched trench 312.

FIG. 4 shows inactive bump pad 365 and inactive bump 380 in line with probe bump 375 and active bump 370. If the VCSEL chip, other than inactive bump 380, would only have active bump 370 and probe bump 375, this location might not provide the required mechanical stability. In such implementations, and generally in any implementation, inactive bump pad 365 and inactive bump 380 would be better located elsewhere.

In some implementations, metal contacts, pads, and traces may be unplated, whereas in other implementations they may be plated with gold, copper, or any other material that improves conductivity or any other electrical or mechanical property.

In some implementations, bumps may be solder bumps, whereas in other implementations bumps may be copper pillars (Cu pillar bumps), gold bumps, indium bumps, or any other material with suitable electrical and mechanical properties. Bumps may be unplated, plated with gold, or plated with any other material that improves conductivity or any other electrical or mechanical property. Some implementations may not have any bumps at all and use hybrid bonding to create electrical and mechanical coupling between the VCSEL chip and another chip on whose surface it is located.

Some implementations use relatively shallow etched trenches, as in FIG. 3, whereas other implementations use much deeper etched trenches that surround both the top reflector and the bottom reflectors.

Some implementations use relatively simple active regions, with only one quantum well, whereas other implementations may use multiple quantum wells, tunnel diodes to separate quantum wells, and/or multiple current apertures to guide the flow of electric current through the VCSEL. Although the examples provided herein describe a bottom-emitting VCSEL, other implementations may use top-emission by implementing high-reflectivity bottom reflectors and partial reflectivity top reflectors.

Bump pads, probe pads, and contact pads may be square, rectangular, circular, hexagonal, octagonal, or any other shape. Whereas current state-of-the-art bumps and pads may have a size of down to ten microns, any future smaller sizes are within the scope and ambit of the disclosed technology. The functional consequences of these tiny sizes are: (1) while probe pad 364 or probe bump 375 may suffer some damage as a result of the probing, the testing will still work; (2) active bondpad 362 and/or active bump 370 will be untouched by the testing, and should function well for subsequent bonding and device operation; and (3) the parasitic capacitance due to these tiny pads is much smaller than that that due to the single much larger pads/bumps of conventional designs, enabling the device to work well in high-bandwidth applications. In other words, by reconfiguring one large pad into two significantly smaller ones, they may be separately optimized for two different functions, providing corresponding improvements in device yield and operating performance.

### Particular Implementations

Described implementations of the subject matter can include one or more features, alone or in combination, as described in the following clauses.

Clause 1. A vertical-cavity surface-emitting laser (VCSEL 310), comprising:
a top surface including an active bondpad (362) and a probe pad (364) interconnected with a VCSEL top contact (360), wherein:
   the probe pad (364) is distinct from the active bondpad (362);
   a patterned metal surface area including the probe pad (364) and the active bondpad (362) is optimized for low parasitic capacitance, the low parasitic capacitance being below 30% above a minimum parasitic capacitance;
   the probe pad (364) is configured for wafer-level testing; and
   the active bondpad (362) is configured for bonding according to a bond technology.

Clause 2. The vertical-cavity surface-emitting laser (310) of clause 1, wherein the bond technology is one of flip-chip bonding and hybrid bonding and wherein the VCSEL is a bottom-emitting VCSEL.

Clause 3. The vertical-cavity surface-emitting laser 310) of clause 1 or clause 2, wherein the probe pad (364) and the active bondpad (362) are substantially circular in shape, viewed from above.

Clause 4. The vertical-cavity surface-emitting laser (310) of any of the clauses 1 to 3, wherein the probe pad (364) is unplated and the active bondpad (362) is plated with one of gold, copper, or another metal.

Clause 5. The vertical-cavity surface-emitting laser (310) of any of the clauses 1 to 4, wherein the minimum parasitic capacitance is a parasitic capacitance of the VCSEL top contact plus a parasitic capacitance of a metal surface area of one thousand (1,000) square microns.

Clause 6. The vertical-cavity surface-emitting laser (310) of any of the clauses 1 to 5, further comprising an active bump (370).

Clause 7. The vertical-cavity surface-emitting laser (VCSEL 310) of any of the clauses 1 to 6, further comprising a probe bump (375).

### Considerations

We describe various implementations of a vertical-cavity surface-emitting laser.

The technology disclosed can be practiced as an apparatus, method, or article of manufacture. One or more features of an implementation can be combined with the base implementation. Implementations that are not mutually exclusive are taught to be combinable. One or more features of an implementation can be combined with other implementations. This disclosure periodically reminds the user of these options. Omission from some implementations of recitations that repeat these options should not be taken as limiting the combinations taught in the preceding sections—these recitations are hereby incorporated forward by reference into each of the implementations described herein.

Although the description has been described with respect to specific implementations thereof, these specific implementations are merely illustrative, and not restrictive. The description may reference specific structural implementations and methods and does not intend to limit the technology to the specifically disclosed implementations and methods. The technology may be practiced using other features, elements, methods and implementations. Implementations are described to illustrate the present technology, not to limit its scope, which is defined by the claims. Those of ordinary skill in the art recognize a variety of equivalent variations on the description above.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Different semiconductor materials can be employed, such as gallium arsenide (GaAs), aluminum gallium arsenide (AlGaAs), silicon, germanium, SiGe, InP, GaN, SiC, diamond, graphene, etc.

It will also be appreciated that one or more of the elements depicted in the drawings/figures can also be implemented in a more separated or integrated manner, or even removed or rendered as inoperable in certain cases, as is useful in accordance with a particular application.

Thus, while specific implementations have been described herein, latitudes of modification, various changes, and substitutions are intended in the foregoing disclosures, and it will be appreciated that in some instances some features of specific implementations will be employed without a corresponding use of other features without departing from the scope and spirit as set forth. Therefore, many modifications may be made to adapt a particular situation or material to the essential scope and spirit.

1. A vertical-cavity surface-emitting laser (VCSEL), comprising:
a top surface including an active bondpad and a probe pad interconnected with a VCSEL top contact, wherein:
the probe pad is distinct from the active bondpad;
a patterned metal surface area including the probe pad and the active bondpad is optimized for low parasitic capacitance, the low parasitic capacitance being below 30% above a minimum parasitic capacitance;
the probe pad is configured for wafer-level testing; and
the active bondpad is configured for bonding according to a bond technology.

2. The vertical-cavity surface-emitting laser of claim 1, wherein the bond technology is one of flip-chip bonding and hybrid bonding and wherein the VCSEL is a bottom-emitting VCSEL.

3. The vertical-cavity surface-emitting laser of claim 1, wherein the probe pad and the active bondpad are substantially circular in shape, viewed from above.

4. The vertical-cavity surface-emitting laser of claim 1, wherein the probe pad is unplated and the active bondpad is plated with one of gold, copper, or another metal.

5. The vertical-cavity surface-emitting laser of claim 1, wherein the minimum parasitic capacitance is a parasitic capacitance of the VCSEL top contact plus a parasitic capacitance of a metal surface area of one thousand square microns.

6. The vertical-cavity surface-emitting laser of claim 1, further comprising an active bump.

7. The vertical-cavity surface-emitting laser of claim 1, further comprising a probe bump.
